(19) United States
(12) Patent Application Publication
(10) Pub. No.: US 2024/0220865 A1
(43) Pub. Date: Jul. 4, 2024

(54) ESTIMATING PARAMETERS OF A MODEL THAT IS NON-LINEAR AND IS MORE COMPLEX THAN A LOG-LINEAR MODEL

(71) Applicant: Technion Research & Development Foundation Limited, Haifa (IL)

(72) Inventors: Mordechay Pinchas Freiman, Zichron Yaakov (IL); Shira Nemirovsky-Rotman, Haifa (IL)

(73) Assignee: Technion Research & Development Foundation Limited, Haifa (IL)

(21) Appl. No.: 18/557,588

(22) PCT Filed: Apr. 25, 2022
(86) PCT No.: PCT/IB2022/053833

§ 371 Date: Oct. 27, 2023

Related U.S. Application Data
(60) Provisional application No. 63/201,391, filed on Apr. 27, 2021.

(51) Int. Cl. G06N 20/00

(52) U.S. Cl. CPC G06N 20/00

(57) ABSTRACT

A method for estimating parameters of a model that is non-linear and is more complex than a log-linear model, the method may include feeding measured observations and sampling coordinates of the measured observations to a machine learning process; and processing the measured observations and the sampling coordinates of the measured observations, by the machine learning process, to provide an estimate of the parameters of the model; wherein the model is indicative of a relationship between the measured observations and the sampling coordinates.

### CROSS REFERENCE

This application claims priority from U.S. provisional Ser. No. 63/201,391, patent filing date Apr. 27, 2021 which is incorporated herein by reference.

### BACKGROUND

The multi-exponential fitting problem appears in various science and engineering applications, such as nuclear magnetic resonance spectroscopy, lattice quantum chromodynamics, pharmaceutics and chemical engineering, fluorescence imaging, infra-red imaging, economic model prediction, medical imaging, and more.

While the fitting of mono-exponential models is fairly straight forward through linearization by a logarithm, the fitting of multi-exponential models remains a challenge. The main approach is the non-linear least squares regression and its variants. The segmented least-squares method approximates the solution by decomposing the estimation problem into a combination of a linear component for part of the parameter estimations, and a non-linear component for other parameter estimations. The more recent variable projection approach decomposes the non-linear estimation problem into a set of linear problems, in order to achieve more reliable parameter estimates. While these approaches are computationally efficient, they still require a relatively high SNR in order to produce reliable estimates. In the context of medical imaging, Bayesian approaches utilizing different priors including Shrinkage and Spatial homogeneity priors among others, were suggested to improve overall robustness. However, these methods are very time-consuming and highly sensitive to the pre-defined prior.

Recently, deep-learning methods in the form of multi-layer perceptron approaches were suggested for multi-exponential model fitting in the context of intra-voxel incoherent motion imaging with substantial improvement, in terms of both estimation reliability and computational time, over classical non-linear regression. However, these methods are still highly sensitive to the training conditions in general, and to the assumed exponential model parameters and signal-to-noise ratio in particular. Therefore, they cannot be reliably used in practice.

### BRIEF DESCRIPTION OF THE DRAWINGS

The embodiments of the disclosure will be understood and appreciated more fully from the following detailed description, taken in conjunction with the drawings in which:

FIG. 1 illustrates an example of a relation between sampling coordinates and observations;

FIG. 2 illustrates an example of a neural network;

FIG. 3 illustrates an example of a neural network;

FIG. 4 illustrates an example of one or more results of an experiment;

FIG. 5 illustrates an example of one or more results of an experiment;

FIG. 6 illustrates an example of one or more results of an experiment;

FIG. 7 illustrates an example of one or more results of an experiment;

FIG. 8 illustrates an example of one or more results of an experiment;

FIG. 9 illustrates an example of a method; and

FIG. 10 illustrates an example of a computerized process.

### DESCRIPTION OF EXAMPLE EMBODIMENTS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference in the specification to a method should be applied mutatis mutandis to a device or system capable of executing the method and/or to a non-transitory computer readable medium that stores instructions for executing the method.

Any reference in the specification to a system or device should be applied mutatis mutandis to a method that may be executed by the system, and/or may be applied mutatis mutandis to non-transitory computer readable medium that stores instructions executable by the system.

Any reference in the specification to a non-transitory computer readable medium should be applied mutatis mutandis to a device or system capable of executing instructions stored in the non-transitory computer readable medium and/or may be applied mutatis mutandis to a method for executing the instructions.

Any combination of any module or unit listed in any of the figures, any part of the specification and/or any claims may be provided.

The specification and/or drawings may refer to a processor. The processor may be a processing circuitry. The processing circuitry may be implemented as a central processing unit (CPU), and/or one or more other integrated circuits such as application-specific integrated circuits (ASICs), field programmable gate arrays (FPGAs), full-custom integrated circuits, etc., or a combination of such integrated circuits.

Any combination of any steps of any method illustrated in the specification and/or drawings may be provided.

Any combination of any subject matter of any of claims may be provided.

Any combinations of systems, units, components, processors, sensors, illustrated in the specification and/or drawings may be provided.

There may be provided a method, a system, and a computer readable medium for estimating parameters of a model that is non-linear and is more complex than a log-linear model.

The following text refers to a multi-exponential model or to a multi-exponential fitting. This is an example of a model that is non-linear and is more complex than a log-linear model and to a fitting related to such a model.

The following text refers to a neural network. This is merely an example of a machine learning process. The structure of the neural network, the number of hidden layers, the connectivity between layers, and the number of nodes per layer are merely a non-limiting example.

There are provided a method, a system and a non-transitory computer readable medium for addressing the challenge of reliable multi-exponential fitting, that are also referred to a MELoDee (Multi-Exponential model Learning based on Deep neural networks), which is a new deep-learning-based solver, which may include a new neural network architecture as well as a novel training protocol, aimed at producing a multi-exponential fitting solution that is more accurate, precise and robust to uncertainties in the training conditions.

It should be noted that the MELoDee may be applied mutatis mutandis on models that are not multi-exponential but are non-linear and are more complex than a log-linear model.

MELoDee fits, or estimates, parameters of a multi-exponential model, which may be expressed in the general form:

$$\\ \begin{matrix}y = {f}_{Θ} ( x ) & [ 1 ]\end{matrix}$$

Where Θ=(θ₁, θ₂, θ₃, . . . ) is the set of parameters that needs to be estimated; f_{Θ}(·) is model that is defined according to Θ; y are the (presumably given) measurements; and x are sampling coordinates, which determine the quantitative relations between y and Θ.

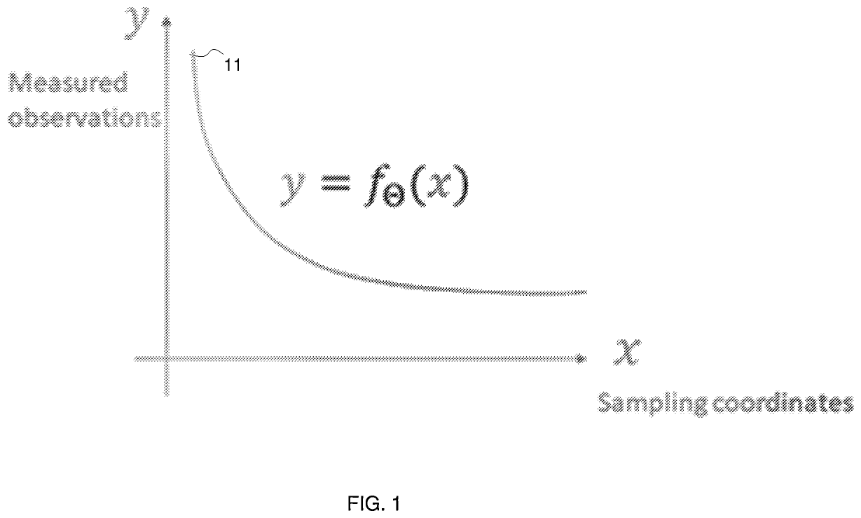

FIG. 1 illustrates a relation (curve 11) between the sampling coordinates (x-axis) and the observations (y-axis) that is given by the function ƒ_{Θ}(x), which is a multi-exponential sum. Θ is the vector of model parameters, which should be estimated when given the measured observation vector y sampled at the sampling coordinates x.

The fitting problem involves the estimation of the set of parameters Θ from the given measurements y and their associated sampling coordinates x.

Classical methods use the non-linear least squares approach to estimate the model parameters:

$$\\ \begin{matrix}\hat{Θ} = arg {min}_{Θ} {‖ y - {f}_{Θ} ( x ) ‖}^{2} & [ 2 ]\end{matrix}$$

with a non-linear solver, such as the Levenberg-Marquardt algorithm. However, these methods are time-consuming, subject to the initialization of the solver and sensitive to noise.

Deep-neural-network architectures previously proposed in order to solve such a problem typically may include an input layer that is solely comprised of the measurements y, and an output layer that may include the estimated model parameters.

Formally, during the training process the network F_{Φ} weights (Φ) are found by minimizing, for example, the squared norm between the signal generated by the multi-exponential model f_{Θ} with the parameters θ predicted by the network F_{Φ} and the observed signal y:

$$\\ \begin{matrix}\hat{Φ} = arg {min}_{Φ} {‖ y - {f}_{θ} ( x , {F}_{Φ} ( y ) ) ‖}^{2} & [ 3 ]\end{matrix}$$

After the training process, the network F_{Φ} can be used directly to infer the multi-exponential model parameters from the input signal y. However, the training process of such architectures implicitly presumes, that the model sampling coordinates are known and fixed. Therefore, while the network may learn how to predict the multi-exponential model parameters θ in a specific scenario, it can't generalize the model to additional scenarios. This is especially important in the real-world context, where both the measurements y and the sampling coordinates x, which determine the relations between y and Θ, may be perturbed by both measurement noise and unknown variations Δx, in the sampling coordinates, which can be expressed as:

$$\\ \begin{matrix}\tilde{x} = x + Δ x . & [ 4 ]\end{matrix}$$

Further, the lack of ability to generalize the multi-exponential model may result in over-fitting to the training data which will result in sub-optimal prediction of the multi-exponential model even for the specific scenario the network was trained for.

To mitigate these issues, there is proposed the MeLoDee architecture and training approach such that it will consist of not only the measurements y, but, in addition, the sampling coordinates x. This modified network architecture is applied with an appropriate-tailored training protocol.

According to this protocol, the training data may be generated as a matrix, whose each row may include the measurements y concatenated to the corresponding sampling coordinates x. During the training process, a preliminary reference sampling coordinates' vector is set, and for each row of the training matrix, the sampling coordinates are modified such that each coordinate is randomly biased (or perturbed) in the following manner:

$$\\ \begin{matrix}{x}_{i}^{{}_{} var} = {x}_{i}^{{}_{} ref} + {u}_{i} {x}_{i}^{{}_{} ref} , {u}_{i} \sim 𝒰 ( - R , + R ) , 0 < R < 1 & [ 5 ]\end{matrix}$$

Where: xᵢ^{ref}—reference value for sampling coordinate xᵢ; uᵢ—a uniformly distributed (˜ [symbol] (·)) random variable, in the range of (−R, +R), for a constant 0<R<1, xᵢ^{var}—varied value for the sampling coordinate xᵢ.

The above equation specifies the manner in which the i-th sampling coordinate, namely xᵢ, is varied for each of the training set data during the training process. Each xᵢ is randomly biased according to a uniformly distributed random variable uᵢ over the range (−R, +R), which sets the percentage of the change in xᵢ relative to its reference (original) value xᵢ^{ref}. 0<R<1 is a constant that is determined prior to the training phase. In this context, it is also important to note that the subscript i in xᵢ signifies that for each sampling coordinate xᵢ, the variation is randomly chosen, in a statistically independent manner with respect to the other xᵢs′ variations. Applying this protocol of xᵢ modified values enables to train the network with a wide range of variation scenarios, in order to increase its potential robustness to uncertainties in the sampling coordinate parameters, as well as to other possibly inherent random noise.

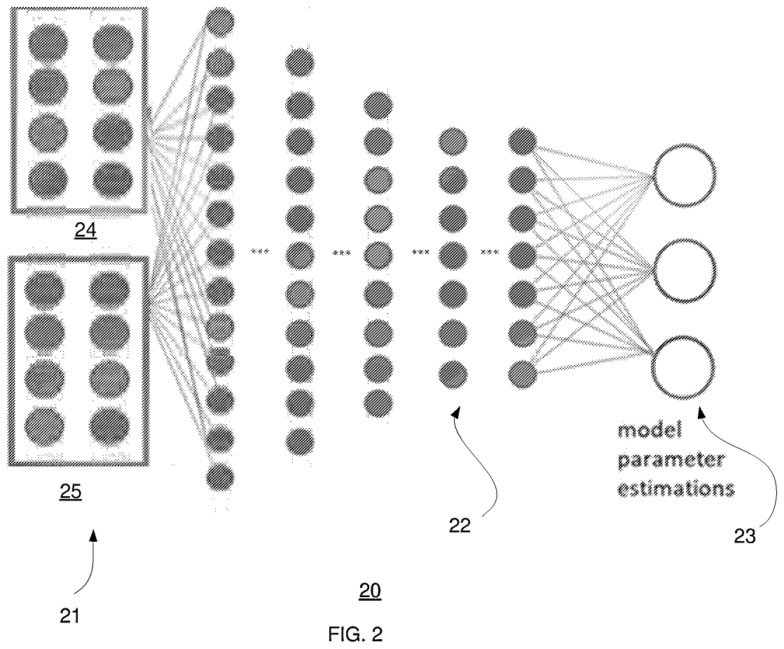

There is provided a definition of a neural-network F 20 with the architecture described in FIG. 2 and weights Φ that receive the observations (y) and the sampling coordinates (x) as input and predict the model parameters Θ.

In FIG. 2 the neural-network 20 may include input layer 21, hidden layers 22 and output layer 23. The input layer 21 is fed by observations 24 and perturbed sampling coordinates 25.

Self-supervised training procedure is then applied to determine the network's weights (F_{Φ}) that minimize an objective function such as:

$$\\ \begin{matrix}\hat{Φ} = arg {min}_{Φ} {‖ y - {f}_{θ} ( x , {F}_{Φ} ( x , y ) ) ‖}^{2} & [ 6 ]\end{matrix}$$

using standard deep-learning optimization techniques.

Model fitting—After proper training, the resulting network F_{Φ} can be used to predict the model parameters Θ, given observations and their sampling coordinates as input, as follows:

$$\\ \begin{matrix}\hat{Θ} = {F}_{Φ} ( x , y ) & [ 7 ]\end{matrix}$$

Where \hat{Θ} are the required estimations of the model parameters.

### Medical Imaging Application—Diffusion-Weighted MRI, Intravoxel Incoherent Motion Model Parameter Estimation

### Diffusion-Weighted MRI and the Intra-Voxel Incoherent Motion Model (IVIM)

Diffusion-Weighted MRI (DW-MRI) is an imaging technique that relies on the random motion of water molecules in the body. The movement of water molecules in a biological tissue is the result of interactions with cell membranes and macro-molecules. In the presence of magnetic field pulses, movement and displacement of the water molecules in the tissue occurs, which results in signal attenuation.

The degree of restriction to water molecules movement (diffusion) in the tissue is inversely correlated to the tissue cellularity and the integrity of cell membranes, and may be quantified in the DW attenuation model by the diffusion coefficient. Specifically, the DW weighted signal is the result of the motion of water molecules in the extracellular space, the intracellular space and the intravascular space. Due to blood flow, water molecules in the intravascular space typically have a greater diffusion distance compared to the intracellular and extracellular spaces.

This motion in the intravascular space is termed “pseudo-diffusion”, while the intracellular and extracellular space motion is described by the diffusion coefficient.

The sensitivity of the DW signal attenuation to water motion is related to the MRI scanner's acquisition parameter, also known as the “b-value”, which is proportional to the amplitude of the magnetic field gradient.

In accordance with the discussion above, the overall DW-MRI attenuation may be modelled according to the “Intra-Voxel Incoherent Motion Model” (IVIM) proposed by Le-Bihan, who suggested a sum of the diffusion and pseudo-diffusion components, taking the shape of a bi-exponential decay:

$$\\ \begin{matrix}{s}_{i} = {S}_{0} ( {F}_{p} {e}^{{}_{} - {b}_{i} ( {D}_{p} + D )} + ( 1 - {F}_{p} ) {e}^{{}_{} - {b}_{i} D} ) , & [ 8 ]\end{matrix}$$

Where sᵢ is the signal at b-value bᵢ; S₀ is the signal without sensitizing the diffusion gradients; D is the diffusion coefficient, an indirect measure of tissue cellularity; Dₚ is the pseudo-diffusion coefficient, an indirect measure of blood flow in the micro-capillaries network; and Fₚ is the fraction of the contribution of the pseudo-diffusion to the signal decay, which is related to the percentage volume of the micro-capillary network within the voxel.

The IVIM model parameters have recently been shown to serve as promising quantitative imaging biomarkers for various clinical applications in the body, including the differential analysis of tumors, as well as the assessment of liver cirrhosis and Crohn's disease. For example, for the case of tumors that show increased vascularity, the contribution of the pseudo-diffusion component to the attenuation in the DW-MRI model will account for a significant portion.

MELoDee for IVIM parameter estimation from DW-MRI data

A feed-forward back-propagation deep neural network was trained using data generated according to the IVIM model (see equation [8]). The proposed network is composed of five fully-connected hidden layers, an extended input layer and an output layer.

As explained above, the input layer is extended in the sense that, in addition to the attenuated DW signals, it may include the b-values by which the IVIM data is generated. More specifically, for each line of data in the input matrix, where the b-values are concatenated to the attenuated signals, the randomly noised (or perturbed) b-values are inputted. In this manner, the network is able to learn the “real” IVIM physical model, which strongly depends on the b-values.

This extended input layer is one of the difference between our MELoDee architecture and the previously proposed architecture (IVIM-NET), proposed by Bariberi et al.

The input layer of the proposed network may include twice the neurons in IVIM-NET. For example, for an acquisition b-values vector of length 8, the proposed network's input may include 16 neurons, while the input layer of the network of Barbieri includes 7 neurons (the signal associated with b=0 is typically omitted as the other signals are normalized according to it).

Accordingly, the proposed network's input layer may include 14 inputs (7 attenuated signals+7 b-values, as b=0 and its corresponding attenuated signal are omitted).

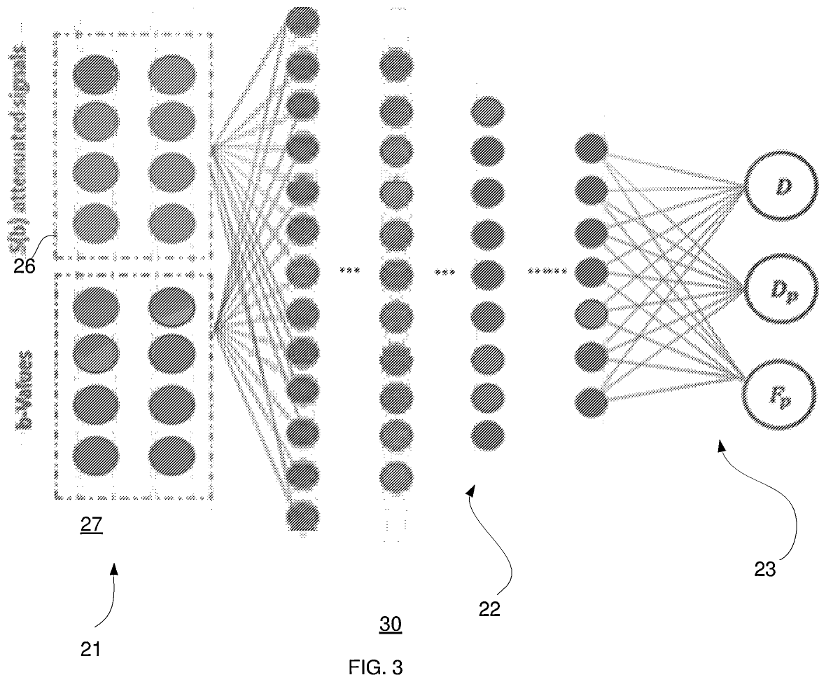

FIG. 3 illustrates an example of a proposed network architecture 30 for the IVIM parameter estimation problem.

The neural-network 30 includes input layer 21, hidden layers 22 and output layer 23. The input layer 21 is fed by S(b) attenuated signals 26 and by b-values 27.

### Experimental Results

In order to demonstrate the performance of the proposed method, the method was evaluated by applying the following series of experiments (over simulated phantoms and clinical IVIM data).

Experiment 1—MELoDee is more robust to b-Values variations compared to IVIM-NET

In this experiment, the previously proposed IVIM-NET and our proposed network, MELoDee, were trained over uniformly random generated samples of the IVIM model parameters. MELoDee was trained according to a permitted range of ˜40% variation in the b-values, while no b-values variations were applied during IVIM-NET training. A simulated phantom that may include the three IVIM parameters maps (D, Dₚ, Fₚ), and its corresponding IVIM model data, were generated for the validation step. The validations of IVIM-NET and MELoDee networks were then processed over a simulated phantom where a 35% variation was applied over the b-values.

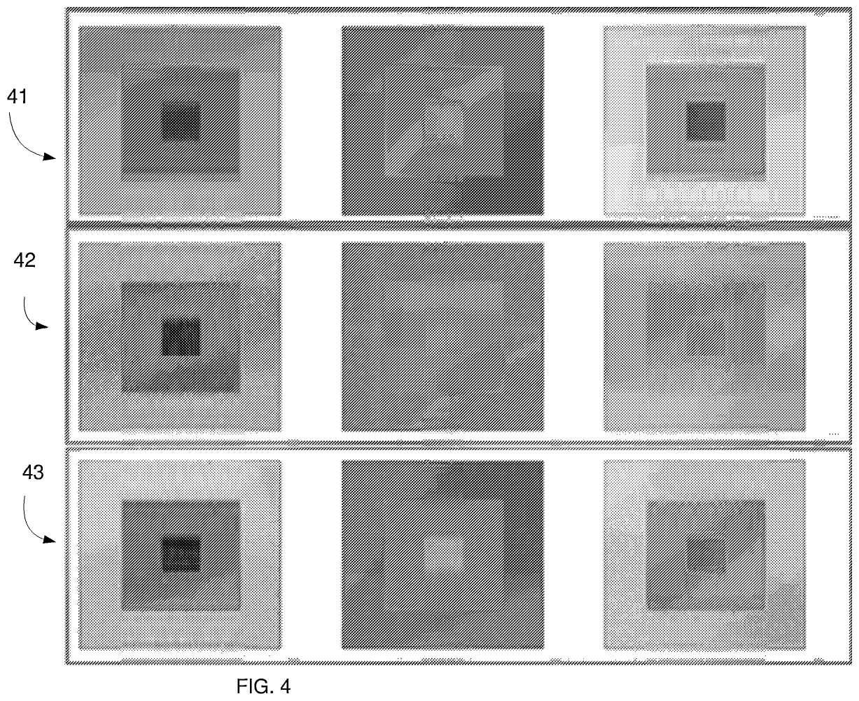

The obtained results are shown in FIG. 4. The left column of images refers to Dₚ (values of pixels—range between zero and 0.1), the middle column refers to D (values of pixels—range between zero and 0.003), and the right column refers to Fₚ (values of pixels—range between zero and 0.5), whereas lower valued pixels are darker. As may be seen in FIG. 4, MELoDee (results located at the bottom row and denoted 43) was able to obtain estimation that significantly better resembled the original Ground Truths (located at the upper row and denoted 41) of the IVIM parameter maps that the IVIM-NET (results located at the middle row and denoted 42).

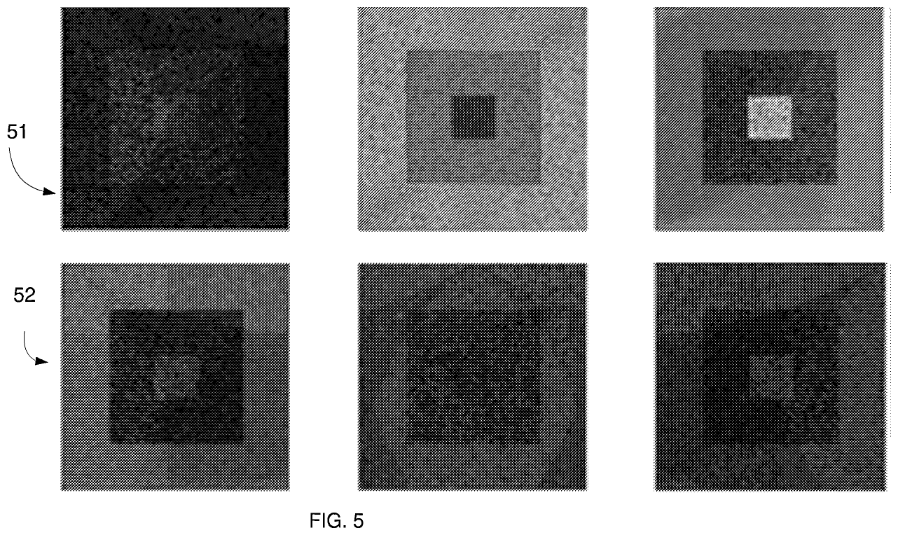

In FIG. 5 the difference maps of the estimations with respect to their corresponding ground truths are shown. It is clear that MELoDee achieves reduced estimation errors compared to IVIM-NET. The top row illustrates the outcome related to INIM-NET (three images denoted 51). The bottom row illustrates the outcome related to MELoDee (three images denoted 52).

The left column of images refers to Dₚ (values of difference pixels—range between zero and 0.05), the middle column refers to D (values of difference pixels—range between zero and 0.001), and the right column refers to Fₚ (values of different pixels—range between zero and 0.2), whereas lower valued pixels are darker.

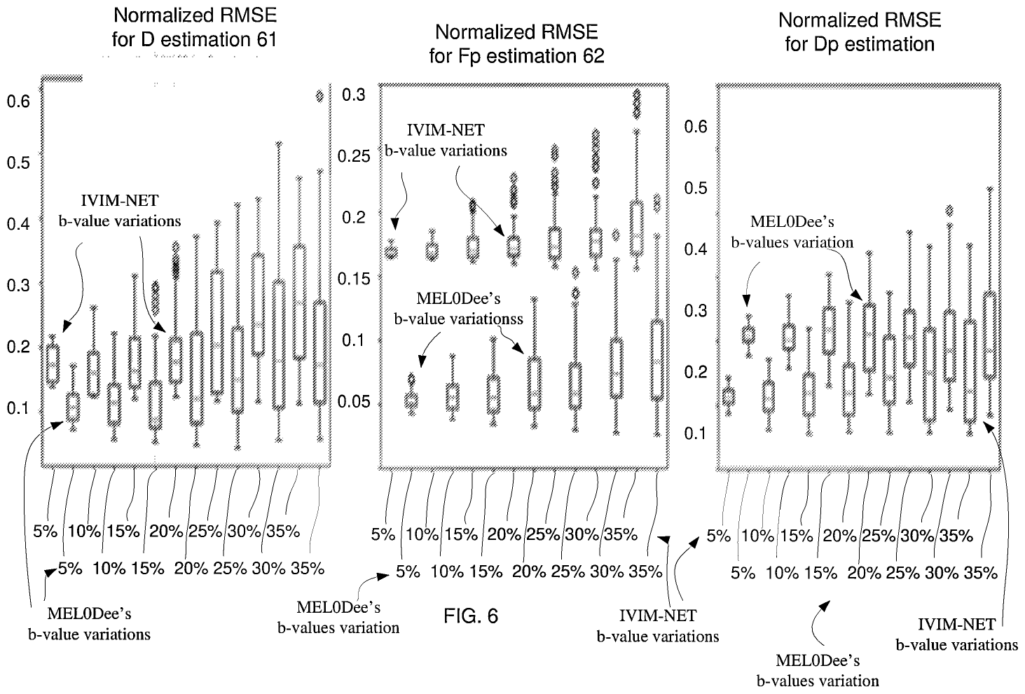

Referring to FIG. 6—illustrating results of experiment 2—the x-axis include alternating values for IVIM-NET b-values variations and MELoDee b-values variations of 5%, 10%, 15%, 20%, 25%, 30% and 35%.

In the left graph (normalized RMSE for D estimation 61) the values (y-axis) span between zero and 0.6. In the middle graph (normalized RMSE for Fₚ estimation 62) the values (y-axis) span between zero and 0.3. In the right graph (normalized RMSE for Dₚ estimation 63) the values (y-axis) span between zero and 0.6.

Experiment 2—MELoDee achieves improved normalized root-mean-squares of its estimations, compared with IVIM-NET.

In this experiment, the same simulated phantom of experiment 1 was used during the validation step. IVIM-NET and MELoDee networks were trained over uniformly distributed parameter maps data, where IVIM-NET was trained with no bias over the b-values, while MELoDee was trained with a permitted 40% variation over the b-values. Validation processes were then applied using both networks, where different permitted variations were applied over the b-values. The following variations were tested: 5%, 10%, 15%, 20%, 25%, 30% and 35%. For each of the permitted variation values, 100 validation experiments were held for each of the networks, where the normalized root-mean-squared errors (NRMSE) of the estimated IVIM parameters with respect to the parameters ground truths were calculated.

The resulting statistics of the NRMSE from this experiment is shown in FIG. 6. As may be seen in FIG. 6, MELoDee achieved improved NRMSEs compared with IVIM-NET, for the D and the Fₚ parameters. For these parameters, MELoDee achieved an approximated 50% reduction in the NRMSE.

In FIG. 6—the x-axis include alternating values for IVIM-NET b-values variations and MELoDee b-values variations of 5%, 10%, 15%, 20%, 25%, 30% and 35%. In the left graph (normalized RMSE for D estimation 61) the values (y-axis) span between zero and 0.6. In the middle graph (normalized RMSE for Fₚ estimation 62) the values (y-axis) span between zero and 0.3. In the right graph (normalized RMSE for Dₚ estimation 63) the values (y-axis) span between zero and 0.6.

Experiment 3—MELoDee achieves improved normalized standard deviations over uniform image areas, compared to IVIM-NET

In this experiment, the same simulated phantom of experiment 1 was applied during the validation step. IVIM-NET and MELoDee networks were trained over uniformly distributed parameter maps data, where IVIM-NET was trained with no bias over the b-values, while MELoDee was trained with a permitted 40% variation over the b-values.

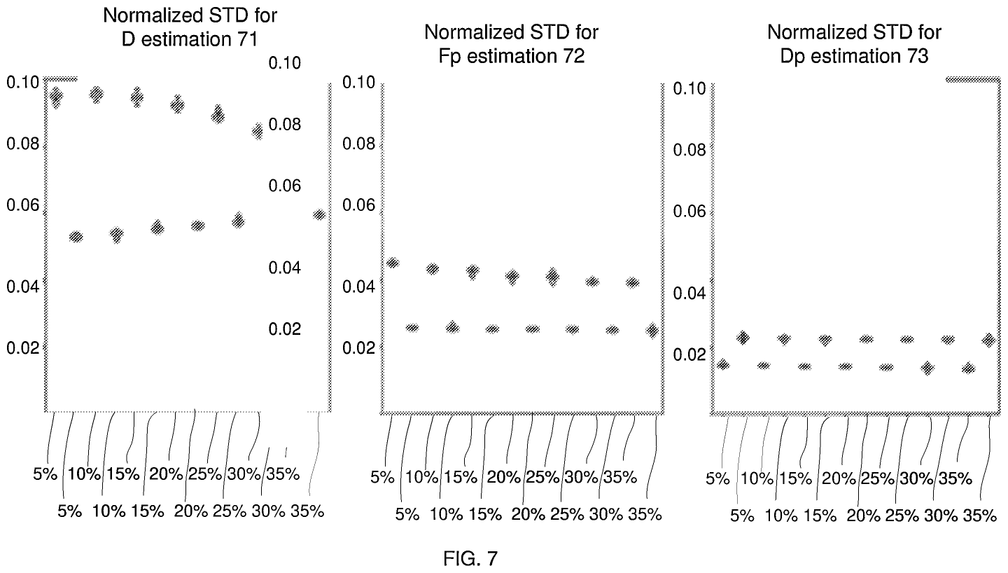

Then, validation processes for both of the compared networks were held, for various b-values variations during the validation steps. The following variations were tested: 5%, 10%, 15%, 20%, 25%, 30% and 35%. For each of the permitted variation values, 100 validation experiments were held for each network, where the modified b-values were kept constant (for each permitted variation value) and random Gaussian noise was generated over the parameter maps. The normalized standard deviation of the estimated parameter maps over areas corresponding to uniform areas in the Ground Truth parameter maps were then calculated. The calculation of these standard deviations was applied for both networks, over 100 validation experiments with randomly generated Gaussian additive noise, and for each of the b-values variations of the validation step. The results are shown in FIG. 7.

As may be seen in FIG. 7, MELoDee was able to obtain significantly reduced standard deviations over uniform areas in the image, for the D and Dₚ parameters. MELoDee achieved an approximated 50% reduction in the normalized standard deviations compared to IVIM-NET for these parameters. It is important to note that lower standard deviations in the estimated parameter maps, calculated over areas that are uniform in the ground truth maps, correspond to higher noise robustness. This result thus demonstrates the improved robustness of MELoDee to additive Gaussian noise, which may serve as a good approximation to the physical noise added when acquiring the DW-MRI data.

The results are shown in FIG. 7. In FIG. 7, the left graph (Normalized STD for D estimations) correspond the classical linear least squares solver estimations. The middle graph (Normalized STD for Fₚ estimates 72) to the IVIM-NET predictions, and the right graph (Normalized STD for Dₚ estimates 73) to the MELoDee estimations. In the left graph the values (y-axis) span between zero and 0.1. In the middle graph the values (y-axis) span between zero and 0.1. In the right graph the values (y-axis) span between zero and 0.1.

Experiment 4—MELoDee achieves improved estimated parameters maps on upper abdomen clinical images compared to IVIM-NET

In this experiment, the estimation performance of IVIM-NET and MELoDee were compared over clinical upper abdomen data.

Both networks were trained over uniformly distributed parameter maps data, where IVIM-NET was trained with no bias over the b-values, while MELoDee was trained with a permitted 10% variation over the b-values. It should be noted that the same b-values that were used to acquire the clinical data were used during the training process. Then, validation was applied for the input data, for both networks.

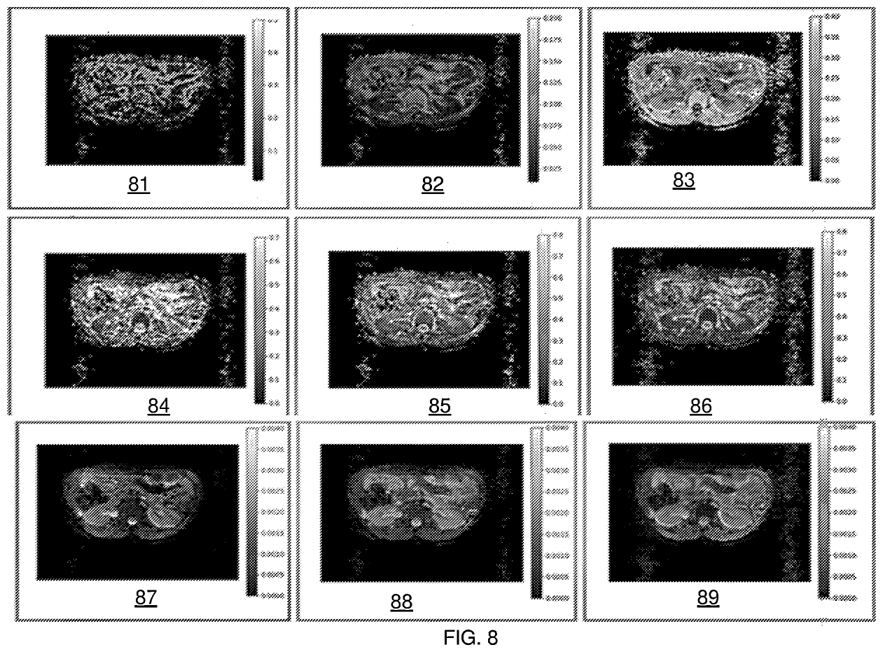

FIG. 8 illustrates the results of experiment 4. There are nine images denoted 81-89 that are arranged in three columns and three rows. The left column illustrates the outcome of non-least square regression illustrates the outcome of IVIM-NET, and the right column illustrated the outcome of MELoDee. The upper row illustrates \hat{D}ₚ, the middle row illustrates \hat{F}ₚ, and the lower row illustrates \hat{D}.

As may be qualitatively seen in FIG. 8, MELoDee was able to obtain parameter maps that better preserve details and edges in the images, as well as reduced noise over uniform areas in the image.

There has been provided a MELoDee, a new neural network architecture and training method for multi-exponential model fitting.

The proposed method exhibits an extended input architecture, that includes of both the measurement and the sampling coordinates. The method also exhibits an appropriate training protocol, were the sampling coordinates are randomly perturbed. These two features enable the network to generalize the multi-exponential model better than previously thought approaches, and thus to provide with more accurate and robust model parameter estimations.

The previous text demonstrated the performance of MELoDee for the case of IVIM imaging, for a simulated phantom and real clinical upper abdomen data.

It has been shown that the MELoDee improved the D and Fₚ parameter estimates normalized RMSE by approximately 50% compared to the previously proposed IVIM-NET.

MELoDee achieved an approximated 50% reduction in the normalized standard deviations over uniform areas in the image for the D and Dₚ parameter estimates compared to IVIM-NET.

MELoDee provided improved estimated parameters maps for clinical IVIM data—in the sense of better edges and details preservation, as well as reduced noise over uniform areas.

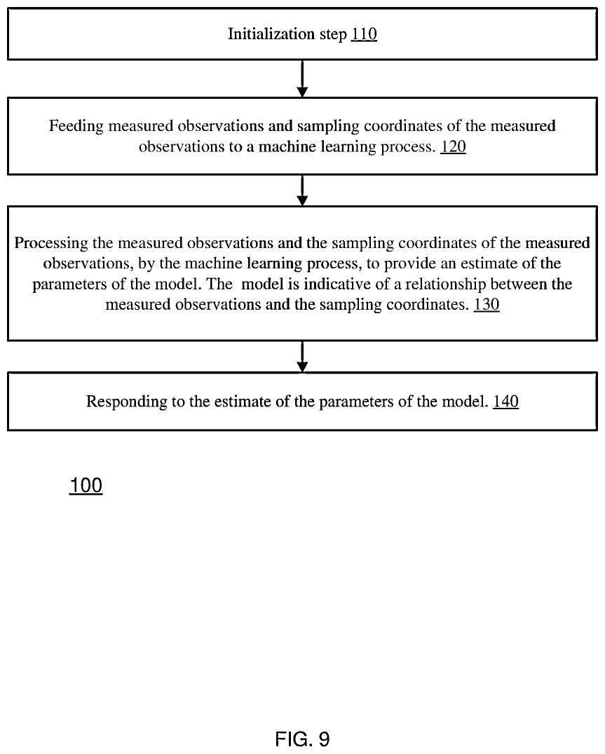

FIG. 9 is an example of method 100.

Method 100 is for estimating parameters of a model that is non-linear and is more complex than a log-linear model.

The model may be a multi-exponential model.

The model may be a diffusion weighted magnetic resonance imaging model.

Method 100 starts by initialization step 110. The initialization step 110 may include training a machine learning process, receiving a trained machine learning process, or receiving a partially trained neural network and training it.

Initialization step 110 may include receiving a machine learning process that is trained during a training period in which the machine learning process is fed by training observations and training sampling coordinates. Some of the training sampling coordinates may be generated by randomly biasing initial training sampling coordinates to provide randomly biased training sampling coordinates. The term initial means before being randomly biased. Some of the training observations represent estimated training observations obtained at the randomly biased trained sampling coordinates.

Initialization step 110 may include training the machine learning during a training period, wherein the training may include feeding the machine learning process by training observations and training sampling coordinates. This may include generating some of the training sampling coordinates by randomly biasing initial training sampling coordinates to provide randomly biased training sampling coordinates. This may include obtaining some of the training observations at the randomly biased trained sampling coordinates. The training may be supervised, unsupervised or a combination of supervised and unsupervised.

The training observations may be real/actual observations (for example sensed information), but may be simulated, estimated or any other not actually measured observations.

Step 110 may be followed by step 120 of feeding measured observations and sampling coordinates of the measured observations to a machine learning process.

Step 120 may include feeding the measured observations and sampling coordinates of the measured observations to an input stage of the machine learning process. For example—each node of the input stage may receive the measured observations and sampling coordinates of the measured observations. Yet for another example—at least one of the nodes of the input steps may receive only a few (one or more) of the measured observations and/or only a few (one or more) of the coordinates.

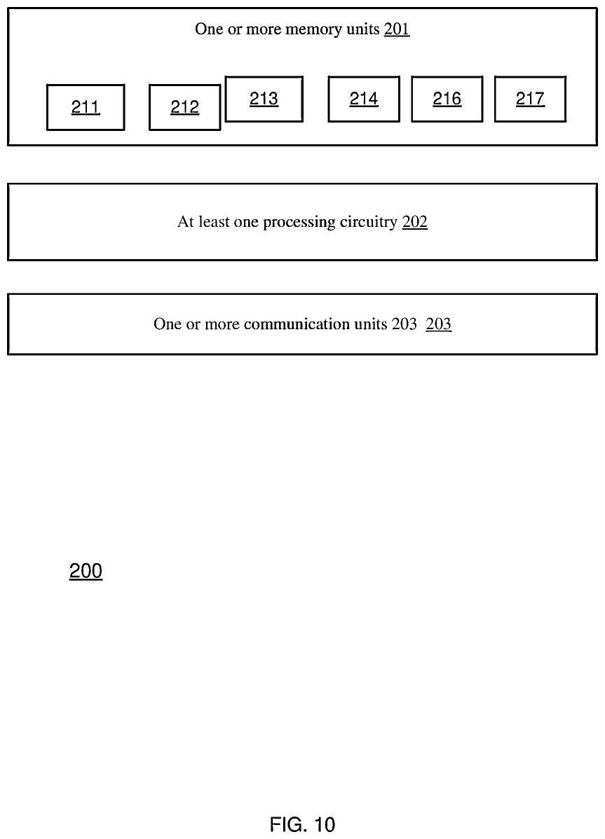

The machine learning process may be implemented by one or more neural network. A neural network may be a deep neural network or differ from a deep neural network. An example of a neural network is feed-forward back-propagation deep neural network. The neural network may include multiple fully connected layers or may differ from such a network. The neural network may be implemented by using a neural network processor such as one or more integrated circuits—that may include a neural network hardware accelerator. See, for example FIG. 10 illustrates a computerized system 200 configured to execute method 100. Computerized system 200 may include (i) one or more memory units 201 configured to store instructions 211 and/or inputs (such as but not limited to measured observations 212 and sampling coordinates of the measured observations 213) and/or other information 214 (for example configuration and/or weights or any other metadata of a machine learning process), and/or model parameters 215 of model 216, (ii) at least one processing circuitry 202 that may be implemented as a central processing unit (CPU), and/or one or more other integrated circuits such as application-specific integrated circuits (ASICs), field programmable gate arrays (FPGAs), full-custom integrated circuits, etc., or a combination of such integrated circuits. The one or more processing circuitry 202 may access the one or more memory units during the execution of method 100. The computerized system 200 may include one or more communication units 203 for communication with computerized entities outside the computerized system, and/or for communication within the computerized system. Any communication protocol can be provided. The machine learning process may be implemented by the one or more processing circuits and/or by any other part of the computerized process. The machine learning process can be trained by computerized system 200 or by another computerized system.

Step 120 may be followed by step 130 of processing the measured observations and the sampling coordinates of the measured observations, by the machine learning process, to provide an estimate of the parameters of the model. The model is indicative of a relationship between the measured observations and the sampling coordinates.

Step 130 may be followed by step 140 of responding to the estimate of the parameters of the model. This may include applying the model, storing the model, sending the model, uploading the model to a cloud computing environment, generating MRI results, and the like.

The method allows to estimate of the parameters of the model using fewer (for example—a reduction of 50% percent and even more) measured observations—which saves computational resources and memory resources—and also improves the accuracy of the model—when used with a certain number of measured observations. The method also allows to solve one of the bottlenecks of the generation of a model—the acquisition of a sufficient number of measured observations. Thus the suggested method may allow to build a model even if there are not enough measured observations to build it—at the absence of the method.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention as claimed.

In the foregoing specification, the invention has been described with reference to specific examples of embodiments of the invention. It will, however, be evident that various modifications and changes may be made therein without departing from the broader spirit and scope of the invention as set forth in the appended claims.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures may be implemented which achieve the same functionality.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

It is appreciated that various features of the embodiments of the disclosure which are, for clarity, described in the contexts of separate embodiments may also be provided in combination in a single embodiment. Conversely, various features of the embodiments of the disclosure which are, for brevity, described in the context of a single embodiment may also be provided separately or in any suitable sub-combination.

It will be appreciated by persons skilled in the art that the embodiments of the disclosure are not limited by what has been particularly shown and described hereinabove. Rather the scope of the embodiments of the disclosure is defined by the appended claims and equivalents thereof.

We claim:

1. A method for estimating parameters of a model that is non-linear and is more complex than a log-linear model, the method comprises:
feeding measured observations and sampling coordinates of the measured observations to a machine learning process; and
processing the measured observations and the sampling coordinates of the measured observations, by the machine learning process, to provide an estimate of the parameters of the model; wherein the model is indicative of a relationship between the measured observations and the sampling coordinates.

2. The method according to claim 1 wherein the model is a multi-exponential model.

3. The method according to claim 1 wherein the model is a diffusion weighted magnetic resonance imaging model.

4. The method according to claim 1 wherein the machine learning process is trained during a training period in which the machine learning process is fed by training observations and training sampling coordinates.

5. The method according to claim 4 wherein some of the training sampling coordinates are generated by randomly biasing initial training sampling coordinates to provide randomly biased training sampling coordinates.

6. The method according to claim 5 wherein some of the training observations represent estimated training observations obtained at the randomly biased trained sampling coordinates.

7. The method according to claim 5 wherein some of the training observations are simulated.

8. The method according to claim 1 comprising training the machine learning during a training period, wherein the training comprises feeding the machine learning process by training observations and training sampling coordinates.

9. The method according to claim 8 comprising generating some of the training sampling coordinates by randomly biasing initial training sampling coordinates to provide randomly biased training sampling coordinates.

10. The method according to claim 9 comprising obtaining some of the training observations at the randomly biased trained sampling coordinates.

11. The method according to claim 9 wherein some of the training observations are simulated.

12. The method according to claim 1 comprising feeding the measured observations and sampling coordinates of the measured observations to an input stage of the machine learning process.

13. The method according to claim 1 wherein the machine learning process is implemented by a neural network.

14. The method according to claim 13 wherein the neural network is a feed-forward back-propagation deep neural network.

15. The method according to claim 13 wherein the neural network comprises multiple fully connected layers.

16. The method according to claim 1 wherein the machine learning process is trained by a supervised training process.

17. The method according to claim 1 wherein the machine learning process is trained by an un-supervised training process.

18. The method according to claim 1 wherein the machine learning process is trained by a combination of a supervised training process and an un-supervised training process.

19. A non-transitory computer readable medium for estimating parameters of a model that is non-linear and is more complex than a log-linear model, the non-transitory computer readable medium comprises:
feeding measured observations and sampling coordinates of the measured observations to a machine learning process; and
processing the measured observations and the sampling coordinates of the measured observations, by the machine learning process, to provide an estimate of the parameters of the model; wherein the model is indicative of a relationship between the measured observations and the sampling coordinates.

20. The non-transitory computer readable medium according to claim 19 wherein the model is a multi-exponential model.

21. The non-transitory computer readable medium according to claim 19 wherein the model is a diffusion weighted magnetic resonance imaging model.

22. The non-transitory computer readable medium according to claim 19 wherein the machine learning process is trained during a training period in which the machine learning process is fed by training observations and training sampling coordinates.

23. The non-transitory computer readable medium according to claim 19 wherein some of the training sampling coordinates are generating by randomly biasing initial training sampling coordinates to provide randomly biased training sampling coordinates.

24. The non-transitory computer readable medium according to claim 23 wherein some of the training observations represent estimated training observations obtained at the randomly biased trained sampling coordinates.

25. The non-transitory computer readable medium according to claim 23 wherein some of the training observations are simulated.

26. The non-transitory computer readable medium according to claim 19 that stores instructions for training the machine learning during a training period, wherein the training comprises feeding the machine learning process by training observations and training sampling coordinates.

27. The non-transitory computer readable medium according to claim 26 that stores instructions for generating some of the training sampling coordinates by randomly biasing initial training sampling coordinates to provide randomly biased training sampling coordinates.

28. The non-transitory computer readable medium according to claim 27 that stores instructions for obtaining some of the training observations at the randomly biased trained sampling coordinates.

29. The non-transitory computer readable medium according to claim 27 wherein some of the training observations are simulated.

30. The non-transitory computer readable medium according to claim 19 that stores instructions for feeding the measured observations and sampling coordinates of the measured observations to an input stage of the machine learning process.

31. The non-transitory computer readable medium according to claim 19 wherein the machine learning process is implemented by a neural network.

32. The non-transitory computer readable medium according to claim 31 wherein the neural network is a feed-forward back-propagation deep neural network.

33. The non-transitory computer readable medium according to claim 31 wherein the neural network comprises multiple fully connected layers.

34. The method according to claim 1 wherein the machine learning process is trained by a supervised training process.

35. The non-transitory computer readable medium according to claim 1 wherein the machine learning process is trained by an un-supervised training process.

36. The non-transitory computer readable medium according to claim 1 wherein the machine learning process is trained by a combination of a supervised training process and an un-supervised training process.

37. A computerized system that comprises one or more processing circuits and a memory, wherein the one or more processing circuits are configured to:
feed measured observations and sampling coordinates of the measured observations to a machine learning process; and
process the measured observations and the sampling coordinates of the measured observations, by the machine learning process, to provide an estimate of the parameters of the model; wherein the model is indicative of a relationship between the measured observations and the sampling coordinates, wherein the model is non-linear and is more complex than a log-linear model.
